(19) United States
(12) Patent Application Publication
(10) Pub. No.: US 2007/0075435 A1
(43) Pub. Date: Apr. 5, 2007

(54) Semiconductor device

(75) Inventors: Shinji Suminoe, Tenri-shi (JP); Yoko Minamiguchi, Yamatokoriyama-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/540,691

(22) Filed: Oct. 2, 2006

(30) Foreign Application Priority Data
Oct. 5, 2005 (JP) 2005-292859

(51) Int. Cl. H01L 23/52

(52) U.S. Cl. 257/777

(57) ABSTRACT

On a substrate (2), a first package (4) is mounted through bumps (3), and a second package (6) is stacked on the first package (4). Each of the bumps (3) includes: a resin core (3a) having elasticity; and metal layers formed on an outer surface of the resin core. The bumps (3) are arranged so as to provide an electrical connection between the substrate (2) and the first package (4). With the above structure, a stacked semiconductor device is realized in which an IC chip breaks less likely during a mounting process.

This Nonprovisional application claims priority under 35 U.S.C. § 119(a) on Patent Application No. 292859/2005 filed in Japan on Oct. 5, 2005, the entire contents of which are hereby incorporated by reference.

### FIELD OF THE INVENTION

The present invention relates to a semiconductor device having high mounting reliability.

### BACKGROUND OF THE INVENTION

With the movement toward (i) reduction in size and weight and (ii) high functionality of electronic devices such as portable telephones, there has been an increasing demand for high-density mounting of semiconductor devices containing IC chips with improved reliability. In the field of IC packaging, stacked packages have been employed in which a plurality of IC chips are contained in a single package. This is because a mounting area on a substrate can be sufficiently used and the size of the substrate is reduced.

Some of the stacked packages have been put to actual practice which have a stacked structure including flip-chip bonding. A typical example of such stacked structure is disclosed in Japanese Unexamined Patent Publication 326710/1995 (Tokukaihei 7-326710, publication date: Dec. 12, 1995) (Patent Document 1), which will be described below with reference to FIG. 3.

As shown in FIG. 3, the semiconductor mounting structure disclosed in the publication includes: a first bare chip 43, a first reinforcing adhesive 44, die bonding paste 45, a second bare chip 46, wires 47, and a reinforcing adhesive 48, all of which are mounted on or over a printed substrate 41. The first bare chip 43 is mounted on bumps 42 disposed on the printed substrate 41, and the die bonding paste 45 is applied to a rear surface of the first bare chip 43. Further, the second bare chip 46 is mounted on the die bonding paste 45, which is applied on the rear surface of the first bare chip 43. With the wires 47, the second bare chip 46 is connected to the printed substrate 41. Further, the first reinforcing adhesive 44 serves to bond the first bare chip 43 to the printed substrate 41, and the reinforcing adhesive 47 serves to bond the second bare chip 46 to the printed substrate 41.

Further, Japanese Unexamined Patent Publication 299431/2000 (Tokukai 2000-299431, publication date: Oct. 24, 2000) (Patent Document 2) discloses an invention directed to a package having another structure, which is a modification of the structure disclosed in Patent Document 1. In the invention of Patent Document 2, the printed substrate disclosed in Patent Document 1 is used as an interposer substrate. In Patent Document 2, a CSP (Chip Size Package) stacked package is realized in which external output terminals are formed on a surface of the substrate, i.e., the side opposite the surface where ICs are mounted.

Such conventional structures, however, give rise to the following problems.

[Problem 1]

In semiconductor devices including flip chip bonding, electrical connections are provided through metal bumps or solder bumps. Such semiconductor devices are filled with a resin so that ICs and packages are protected and the connections are reinforced. When a temperature changes or moisture absorption occurs, the connection parts have cracks due to stress caused by a difference in absorption coefficient between the metal part and the resin part. This may cause breakage of wires with high possibility.

The problem 1 will be described in more detail, using the semiconductor device disclosed in Patent Document 1 by way of example. FIG. 4 is a cross-sectional view illustrating a structure of the conventional semiconductor device. As shown in FIG. 4, the semiconductor device includes a circuit substrate 51, a first semiconductor chip 52, protruding electrodes 53, a second semiconductor chip 55, a die bonding adhesive 54, wires 56, a support section 57, a coating resin 58, and mounting external terminals 59. The protruding electrodes 53 are provided on electrode pads 52a disposed on the first semiconductor chip 52. The second semiconductor chip 55 is positioned over the first semiconductor chip 52. The second semiconductor chip 55 is connected to the first semiconductor chip 52 through the die bonding adhesive 54. The wires 56 serve to provide interconnections between electrode pads 55a disposed on the second semiconductor chip 55 and electrode pads disposed on the substrate 51, respectively. Further, the support section 57, made by hardening an anisotropic conductive adhesive, fills a space between the first semiconductor chip 52 and the substrate 51. The coating resin 58 serves to protect elements on the top surface of the substrate 51.

When IC chips or packages are stacked in a semiconductor device, in the case of wire bonding, it is preferable that wires be covered with a resin. This prevents electrical shorting and/or breakage of wires due to deformation of wires. Further, it is preferable that surfaces of the IC chips or the like be covered with a resin in order to protect the surfaces of the IC chips and other elements With the above structure, when a space exists inside a semiconductor device, cracks occur during a reflow process for mounting the semiconductor device on a substrate, due to expansion of the air and moisture in the space. Thus, the semiconductor device is filled with a resin so that no space exists inside the semiconductor device.

With the above structure, however, there is a high possibility that the connection parts have cracks due to stress caused by a difference in linear expansion coefficients between the protruding electrodes 53 (metal bumps) and the support section 57 adjacent to the protruding electrodes 53 when a temperature changes, as described above.

[Problem 2]

When IC chips or packages are stacked inside a semiconductor device, a lower package is subjected to stress caused by stacking operation. This may result in cracking of elements on a lower IC chip and/or varying characteristics of the chip. Further, this may result in breakage of a chip itself, in the case of a thin chip.

### SUMMARY OF THE INVENTION

It is an object of the present invention to provide a stacked semiconductor device which has a less possibility that the mounting reliability is reduced during a manufacturing process, and which contains flip chip configuration.

According to the present invention, to attain the foregoing object, there is provided a semiconductor device including: a substrate; a first IC chip mounted over the substrate through a bump; and one or more IC chips stacked over the first IC chip, the bump, including: a core having elasticity; and at least one metal layer formed on an outer surface of the core, the bump being disposed so as to provide an electrical connection between the substrate and the first IC chip.

According to the arrangement, the bump is provided between the first IC chip and the substrate, and the electrical connection is provided therebetween through the metal layer disposed on the outer surface of the bump.

Further, the bump includes the core having elasticity. Thus, stress caused by stacking another IC chip(s) over the first IC chip is absorbed by the core of the bump.

This reduces the possibility that the first IC chip breaks due to stress caused by stacking IC chip(s) over the first IC chip, while ensuring highly reliable bonding using the bump. Further, with the use of the bump that provides the electrical connection between the substrate and the first IC chip, the shock absorbing mechanism is achieved without providing another shock absorbing member. This realizes, with simple operation, a semiconductor device which has high mounting reliability and which is designed with high accuracy.

As described above, according to the present invention, a semiconductor device is realized which has such advantageous effects as (i) reducing, with simple operation, the possibility that the IC chip breaks due do stress caused by stacking the IC chip(s) requiring no additional shock absorbing member, and (ii) having high mounting reliability.

Further, the first IC chip may be a packaged IC chip, or a bare chip which is ready for packaging. Further, IC chip(s) stacked on the first IC chip may be packaged IC chip(s), or bare chip(s) which are ready for packaging.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a cross-sectional view illustrating a structure of a semiconductor device according to one embodiment.

FIG. 2 is a cross-sectional view illustrating a structure of a bump provided in the semiconductor device according to the embodiment.

FIG. 3 is a cross-sectional view illustrating an exemplary structure of a conventional semiconductor device.

FIG. 4 is a cross-sectional view illustrating another structure of the conventional semiconductor device.

### DESCRIPTION OF THE EMBODIMENTS

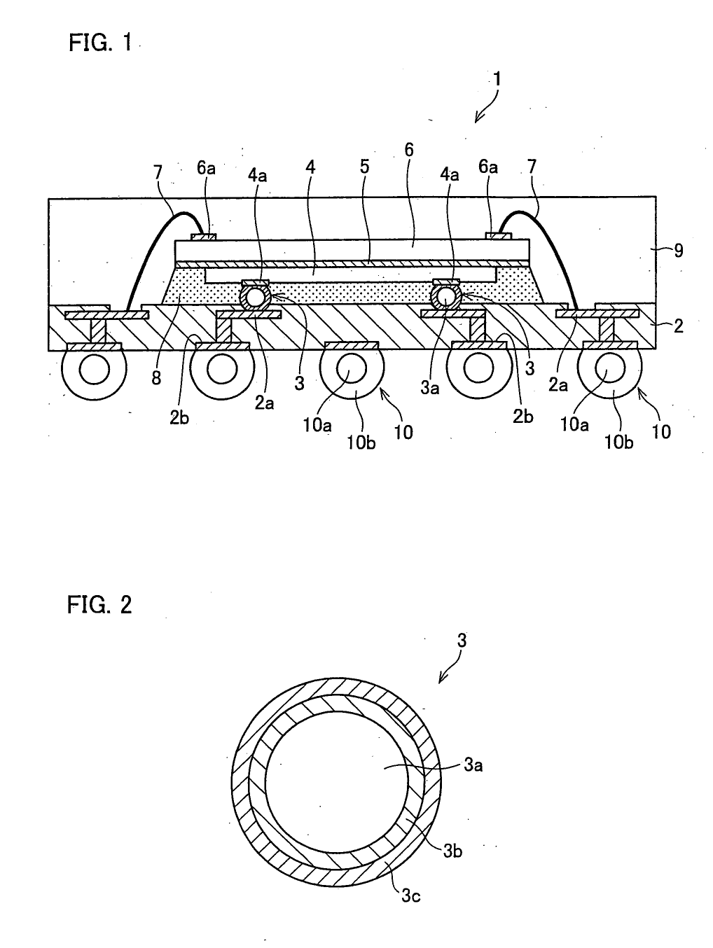

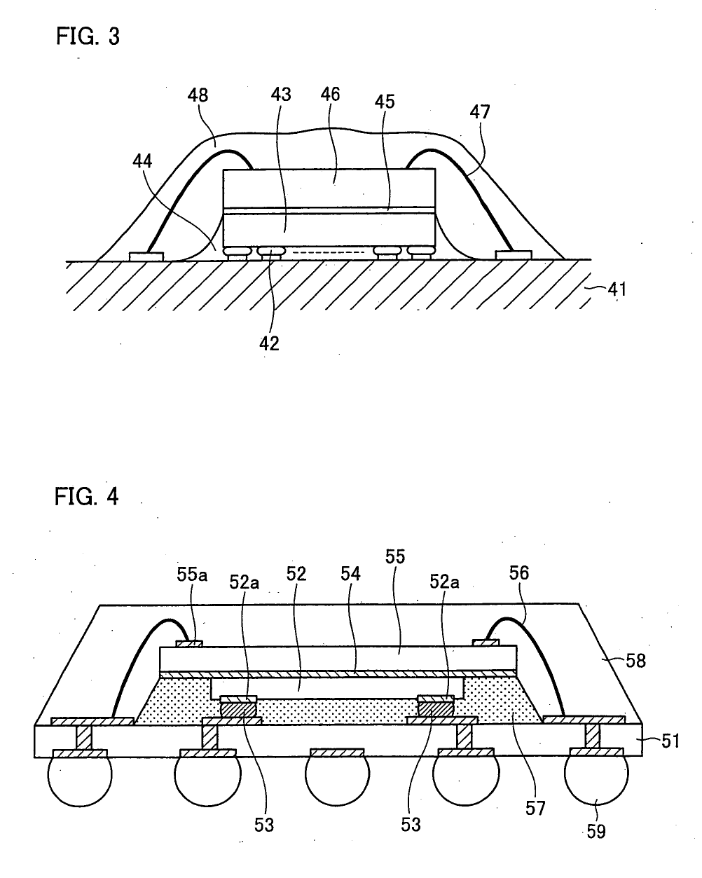

Referring to FIGS. 1 through 2, the following describes one embodiment of the present invention. FIG. 1 is a cross-sectional view illustrating a structure of a semiconductor device 1 according to the present embodiment.

As shown in FIG. 1, the semiconductor device 1 includes a substrate 2, bumps 3, a first package 4 (first IC chip), a second package 6 (IC chip), metal wires 7, a first resin 8 (sealing resin), a second resin 9, and external output terminals 10.

The substrate 2 has electrode pads 2a disposed on one surface, and electrode pads 2b disposed on the other surface. The electrode pads 2a are electrically connected to the electrode pads 2b.

In the first package 4, an IC chip is packaged in a footprint equal in size of the IC chip (wafer level CSP). Further, the first package 4 has electrode pads 4a disposed on its surface, i.e., the side where elements are mounted. The electrode pads 4a are electrically connected through bumps 3 to the electrode pads 2a disposed on the substrate 2.

The IC chip contained in the first package 4 has Al electrode pads. Exclusive of portions where the Al electrode pads are disposed, a surface of the IC chip is covered with a first organic insulating layer. On the organic insulating layer, metal layers are stacked between the Al electrode pads and corresponding external output terminals (not shown). The metal layers include layers made of Ti (500 Å to 5000 Å) and layers made of Cu (3 μm to 20 μm). Further, on top of the metal layers, a second insulating layer (not shown) is formed, exclusive of portions where the electrode pads 4a are disposed. As such, multilevel wiring (rewiring) is realized by the multilevel metal layers.

The bumps 3 serve to connect the substrate 2 and the first package 4 electrically and mechanically, and come in contact with electrode pads 2a of the substrate 2 and the electrode pads 4a of the first package 4. The structure of a bump 3 is shown in FIG. 2.

As shown in FIG. 2, a bump 3 includes: a resin core 3a made of a heat resisting resin; and metal layers, i.e., a copper layer 3b formed on the outer surface of the resin core 3a, and a solder layer 3c provided as the outermost layer.

It is preferable that the resin core 3a have an elastic constant of not less than 500 Mpa and not more than 10 Gpa. This is because, if the resin core 3a has an elastic constant of less than 500 Mpa, the resin core 3a is extremely deformed, possibly causing cracking in the outer metal layers (i.e., the copper layer 3b and the solder layer 3c) and breakage of wires. In the present embodiment, the resin core 3a has an elastic constant of 4.8 Gpa.

Further, a difference in linear expansion coefficients between the resin core 3a and the first resin 8 is within 30 ppm. In the present embodiment, the resin core 3a has a linear expansion coefficient of 40 ppm and the first resin 8 has a linear expansion coefficient of 60 ppm. Thus, a difference in linear expansion coefficients between the resin core 3a and the first resin 8 is 20 ppm.

Further, it is preferable that a difference in linear expansion coefficients between the resin core 3a and the solder layer 3c be within 30 ppm. In the present embodiment, since the solder layer 3c has a linear expansion coefficient of 21.7 ppm, a difference in linear expansion coefficients between the solder layer 3c and the resin core 3a (40 ppm) is 18.3 ppm.

Since the bumps 3 are used inside the package, preferably, the bumps 3 have a restricted height. Considering ease of injecting the first resin 8, the resin core 3a has a diameter of about 20 μm to about 300 μm, e.g. 100 μm. The resin 8 is made of an underfill material, which will be described later.

Further, it is preferable that the copper layer 3b have a thickness of about 3 μm to about 15 μm, and that the solder layer 3c have a thickness of about 5 μm to about 30 μm. Note that, it is desirable that the solder layer 3c be made of Pb free solder composed of, for example, about 96.5% of Sn and about 3.5% of Ag.

One example of the bumps 3 is a solder ball containing a core made of divinylbenzen cross-linked copolymer with heat resistance and elasticity (e.g. micropeal SOL made by Sekisui chemical co., ltd.). Such a solder ball containing a resin core is disposed on each of the electrode pads 2a at a temperature of, for example, about 240° C. during the reflow process, so as to serve as a bump 3.

Compared to typical Pb free solder bumps having a linear expansion coefficient of 21.7 ppm and an elasticity of 41.6 Gpa, the bumps 3 have the following properties: the resin core 3a has a liner expansion coefficients of 40 ppm and an elasticity of 4.8 Gpa. That is, the bumps 3 have a linear expansion coefficient close to that of the first resin 8, i.e., about 60 ppm, while having a low elasticity.

The second package 6 serving as a signal IC chip is bonded to the first package 4 through a die bonding material 5 such that a rear side of the second package 6 and a rear side of the first package 4 face each other. The second package 6 has electrode pads 6a disposed on another surface, i.e., the side where elements are provided.

The metal wires 7 serve to provide electrical connections between the electrode pads 6a of the second package 6 and the electrode pads 2a of the substrate 2.

The external output terminals 10 are terminals via which the substrate is connected to another substrate. The external output terminals 10 are connected to the electrode pads 2b disposed on the rear side of the substrate 2 (the side opposite the surface where IC chips are mounted). Each of the external output terminals 10 includes: a resin core constituted by: a resin core 10a (core); and a solder layer 10b (metal layer) disposed on the outer surface of the resin core 10a. Like the bumps 3, the external output terminals 10 have shock absorbing properties.

The first resin 8, i.e., an underfill material, is filled with a space between the substrate 2 and the first package 4, and a space between the substrate 2 and the second package 6. Further, the second package 6 and the metal wires 7 are encapsulated with the second resin 9 so that no space exists in the semiconductor device. As such, the constituting elements are encapsulated with the resin and thus protected.

Note that, the first resin 8 is made of, for example, an epoxy-based resin, acryl-based resin, or silicon-based resin. Further, the second resin 9 is made of, for example, a mold resin.

[Effects of the Semiconductor Device 1]

In the semiconductor device of the present embodiment, preferably, the internal constituting elements such as the first package 4 and the metal wires 7 are covered with the first resin 8 and the second resin 9 so as to be protected.

When there is a space inside the resin layers, however, cracking may occur in the resin layers adjacent to the space due to stress caused by expansion of air and/or moisture in the space during the reflow process. Further, this may cause breakage of wires on electrical connection parts, for example, such as connections between the bumps 3 and the metal wires 7. Considering this, it is preferable that a resin with good sealing properties be filled so that no air space remains inside the resin layers.

Generally, an underfill material that can be injected to a space between such connection parts has a high linear expansion coefficient. Thus, when the connection parts are made of metal alone, cracking may occur in the connection parts due to stress caused by a difference in expansion coefficient between bumps and resin(s) adjacent to the bumps when a temperature changes. Further, this may cause a faulty electrical connection.

For example, in the case where (i) 49 terminals formed with the solder at 0.5 mm pitches and (ii) solder bumps having a diameter of 300 μm are mounted on a wafer level CSP, and where their mounting properties are tested under a temperature cycling in the range between −40° C. and 125° C., an average life cycle is about 1500. Further, when such a wafer level CSP and solder bumps are covered with the commonly used and repairable first resin 8 (underfill material) having a linear expansion coefficient of 60 ppm, the average life cycle may decrease to about 500. This is caused by a large difference in linear expansion coefficients between the solder (22 ppm) and the first resin 8 (60 ppm).

In such a case, using the bumps 3 improves mounting reliability and increases the average life cycle up to 2500 or more. Further, even when the first resin 8 is injected as an underfill material, the temperature cycle does not decrease much. Further, a faulty connection occurs less likely even when the life cycle exceeds 2500. One of the factors contributing to such improvements is that stress caused by a difference in linear expansion coefficients occurs less likely because the resin core 3a has a linear expansion coefficient of 40 ppm, which is not so different from the linear expansion coefficient of the first resin 8, i.e., 60 ppm. Another factor is that the stress is distributed all over due to the low elasticity of the resin core 3a, i.e., 4.8 Gpa. This allows the stress not to be concentrated on the connection parts of the bumps.

As such, the semiconductor device 1 using the bumps 3 has high mounting reliability and less possibility of a faulty connection due to a temperature change.

Further, in a case where the bumps 3 are used as internal connection terminals to manufacture a stacked semiconductor device containing plural IC chips, a semiconductor device is realized which has a tolerance to temperature change and high mounting reliability.

When a stacked semiconductor device has a restriction on its thickness and thus stacked chips need to have a reduced thickness, the space between the connection parts as well as the size of bumps are made small. This causes difficulty in injecting an underfill material in the space. On the contrary, in the semiconductor device 1 of the present embodiment, the bumps 3 are not made of solder alone and include the resin core 3a. This allows the semiconductor device 1 to have a certain height with less variation, so that the space can be filled completely and stably with the first resin 8, i.e., underfill material.

Generally, an underfill material that is easily injected ensures sealing. However, since such an underfill material has a high linear expansion coefficient, the difference in linear expansion coefficients of the underfill material and metal bumps becomes large, causing difficulties in maintaining tolerance to a temperature change. On the contrary, in the case of the bumps 3, even when an underfill material is used which adheres to and go along a surface of a bump and which can be easily injected to a narrow space, highly reliable mounting is still ensured, while the connection parts have a reduced height. As such, with the bumps 3, stacked structure is realized in a reduced height. Further, using the bumps 3 enables the space between the substrate 2 and the first package 4 to be maintained at a certain height. This allows stable downstream operations, such as wire bonding and die bonding of the second package 6.

Further, when there is a restriction on the thickness of a package, an IC chip of the first package 4 and an IC chip of the second package 6 need to be polished so as to have reduced thickness. In a case where such an IC chip having a reduced thickness is used with conventional bumps, the chip may break due to stress caused by a difference in linear expansion coefficients when a temperature changes.

On the contrary, in the case of the bumps 3, the difference in linear expansion coefficients becomes small, and thus the stress can be reduced. This realizes a reduction in maximum stress even when an IC chip has a reduced thickness, causing breakage of the chip less likely. Further, in the case of the bumps 3, although shocks and stress are caused during a die bonding process for stacking second packages 6 and during a wire bonding process for providing an electrical connection between the stacking second package 6 and the substrate 2, such stress is not concentrated on the bumps. This allows the maximum stress to be small, suppressing the influence on the first chip. This prevents cracking in a surface of the IC chip.

Further, the resin core 3a has an elasticity of 4.8 Gpa, whereas typical solder has an elasticity of 41.6 Gpa. Thus, compared to bumps made of solder alone, the bumps 3 are greater in absorbing shocks and stress caused by stacking IC chips. This reduces the possibility of breakage of an IC chip due to the shocks and stress.

With the above effects, IC chips in a semiconductor device can have a reduced thickness. Further, it becomes possible to stack third and fourth packages and IC chips.

Further, in a semiconductor device in which a plurality of packages and IC chips are stacked, there is a restriction on the thickness of the packages and thus each constituting element has a restricted thickness. This restricts the thickness of the connection parts. For example, there may be a case where a package needs to have a thickness of not more than 100 μm.

In such a case, the connection parts have further reduced tolerance to a temperature change. If bumps are made of metal alone, practically, it is impossible to maintain the tolerance. Even in this case, however, using the bumps 3 containing the resin core 3a, the connection parts have mounting reliability at a practical level regardless of a temperature change during a process. Alternatively, the tolerance to a temperature change can be maintained at a practical level, by using a wafer level CSP which has a reduced thickness to reduce the stiffness of an IC chip itself. In such a wafer level CSP, the thickness is reduced by polishing its rear surface.

[Modification Example]

The present invention is not limited to the description of the embodiments above, but may be altered within the scope of the claims. An embodiment based on a proper combination of technical means disclosed in different embodiments is encompassed in the technical scope of the present invention.

For example, the bumps may have a sphere, hemisphere, or cylinder shape.

Further, not only the second package 6 but also a plurality of packages may be stacked over the first package 4.

Further, a semiconductor element corresponding to the first package 4 and a semiconductor element corresponding to the second package 6 may be packaged IC chips, or bare chips which are ready for packaging.

Further, the external output terminals 10 may be made of solder.

Further, a semiconductor device of the present invention can be mounted on various kinds of electronic devices, for example, such as digital cameras, liquid crystal devices, and personal computers. Electronic devices incorporating a semiconductor device of the present invention are also encompassed in the technical scope of the present invention.

Further, a semiconductor device of the present invention has a core bump structure in which a first package containing an IC chip having plural electrode pads and connection terminal bumps is mounted over a substrate through the bumps, and in which the connection terminal bumps, formed on the electrode pads, contain (i) a material having a low elasticity, and (ii) metal layer(s) disposed on the outer surface of the material. Further, the substrate has external output terminals via which the substrate is connected to another substrate.

Further, the material having a low elasticity is a resin having heat resistance and Young's modulus of not more than 10 Gpa.

Further, it is preferable that the first package be an IC chip, and that a resin core bump be formed directly on an electrode pad of the IC chip.

It is preferable that the first package include an IC chip having rewiring layers including an organic insulating layer and a metal wire layer; and resin core bumps formed on a wafer level CSP on which the electrode pads are rewired.

Further, it is preferable that one or more packages be mounted on the first package, and that electrical connection(s) be provided between the substrate and one of the packages or between some of the substrate and the packages.

Further, it is preferable that the space between the first package and the substrate be filled with the first resin.

Further, it is preferable that packages all electrical connections over the substrate be encapsulated with the second resin.

Further, it is preferable that each of the external output terminals include a resin core bump constituted by (i) a resin having heat resistance and stress absorbing properties, and (ii) metal layer(s) disposed on the outer surface of the resin.

According to the arrangement, the first package is a small package. This realizes a reduction in size of the semiconductor device.

Further, it is preferable that the first package have multilevel wiring including an organic insulating layer and a metal wiring layer.

According to the arrangement, wiring is provided between semiconductor elements containing the IC chip. This improves functionality of the IC chip, thereby realizing a high-functional semiconductor device.

Further, it is preferable that the semiconductor device contain an IC chip having a thickness reduced by polishing its rear surface.

According to the arrangement, the first package can have a reduced thickness. This realizes a reduction in size of the semiconductor device.

Further, the semiconductor device contains an IC chip having a through hole, through which an electrical connection is provided between the top and bottom surfaces of the IC chip.

According to the arrangement, it is possible to draw a wire from a terminal through the through hole. This facilitates mounting of the IC chip.

As described above, it is preferable that the core be made of a material having Young's modulus of not less than 500 Mpa and not more than 10 Gpa.

When the core has Young's modulus of not less than 500 Mpa and not more than 10 Gpa, it is possible to (i) efficiently absorb shocks and stress caused by stacking IC chips, and (ii) prevent breakage of a metal layer disposed on the outer surface of the core due to extreme deformation of the core.

Further, it is preferable that the metal layer include a plurality of layers, and that an outermost layer of the layers be made of solder.

According to the arrangement, the outermost layer of the bump is a solder layer. This makes it possible to perform a reflow process in which the bump can be disposed and mounted on the substrate at an increased temperature. In the reflow process, the bump achieves a self alignment effect when the solder is fused. Thus, the reflow process has an advantageous effect that the position of the bump can be maintained with high accuracy.

Further, another metal layer is formed inside the solder layer. Since the inner metal layer is not fused, the core is still covered by the inner metal layer when the solder layer is fused. This reduces the possibility that metal layer drops from the core and the core is exposed, ensuring that functionality of the bump serving as a connecting element is maintained.

This facilitates the formation of the bump and mounting of IC chips, realizing a high quality semiconductor device with simple operation.

Further, it is preferable that the substrate include an external output terminal via which the substrate is connected to another substrate, and that the external output terminal include (i) a core made of a material having elasticity and (ii) at least one metal layer disposed on an outer surface of the core.

According to the arrangement, the external output terminal can be electrically connected (mounted) to the substrate through the metal layer(s). Further, the external output terminal contains the core having elasticity. Thus, in a case where a temperature change occurs when the semiconductor device is put to actual practice after the mounting process, the connection part would break less likely. This ensures high mounting reliability.

Further, it is preferable that a sealing resin be filled in a space between the substrate and the first IC chip, and that a difference in linear expansion coefficients between the core and the sealing resin be within 30 ppm.

According to the arrangement, an amount of expansion of the bump becomes close to an amount of deformation of the sealing resin around the bump, when a temperature rises during a mounting process or when a temperature changes in use environment where the semiconductor device is integrated in an actual product.

This reduces the possibility that cracking may occur due to a temperature change on the connection part between the first IC chip and the bump. Thus, a semiconductor device is realized which breaks less likely due to a temperature change during a mounting process and/or in use environment.

Further, it is preferable that a difference in linear expansion coefficients between the core and the solder be within 30 ppm.

According to the arrangement, an amount of expansion of the bump becomes close to an amount of deformation of the sealing resin around the bump, when a temperature rises during a mounting process or when a temperature change occurs in use environment where the semiconductor device is integrated in an actual product.

This reduces the possibility that cracking may occur due to a temperature change in the surface of the bump. Thus, a semiconductor device is realized which breaks less likely due to a temperature change during a mounting process and/or in use environment.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor device, comprising:
a substrate;
a first IC chip mounted over the substrate through a bump; and
one or more IC chips stacked over the first IC chip,
the bump, including:
a core having elasticity; and
at least one metal layer formed on an outer surface of the core,
the bump being disposed so as to provide an electrical connection between the substrate and the first IC chip.

2. The semiconductor device according to claim 1, wherein the core is made of a material having Young's modulus of not less than 500 Mpa and not more than 10 Gpa.

3. The semiconductor device according to claim 1, wherein:
the metal layer includes a plurality of layers, and
an outermost layer of the layers is made of solder.

4. The semiconductor device according to claim 1, wherein:
the substrate includes an external output terminal via which the substrate is connected to another substrate, and
the external output terminal includes (i) a core made of a material having elasticity and (ii) at least one metal layer disposed on an outer surface of the core.

5. The semiconductor device according to claim 1, wherein:
a sealing resin is filled in a space between the substrate and the first IC chip, and
a difference in linear expansion coefficients between the core and the sealing resin is 30 ppm or less.

6. The semiconductor device according to claim 3, wherein a difference in linear expansion coefficients between the core and the solder is 30 ppm or less.
